(19) United States
(12) Patent Application Publication
(10) Pub. No.: US 2023/0297731 A1
(43) Pub. Date: Sep. 21, 2023

(54) METHOD AND DEVICE FOR FLOORPLAN GENERATION

(71) Applicant: Tsinghua University, Beijing (CN)

(72) Inventors: Nianxiong LIU, Beijing (CN); Shurui YAN, Beijing (CN); Hang SU, Beijing (CN)

(21) Appl. No.: 18/158,359

(22) Filed: Jan. 23, 2023

(30) Foreign Application Priority Data
Mar. 17, 2022 (CN) 202210266012.3

(51) Int. Cl. G06F 30/13

(52) U.S. Cl. CPC G06F 30/13

(57) ABSTRACT

A method for residential unit floorplan generation, includes obtaining a current status of a floorplan and room information of one or more rooms to be deployed, according to the current status of the floorplan and the room information of the one or more rooms to be deployed, performing multiple Monte Carlo tree searches to obtain a search result, and deploying a room of the one or more rooms to be deployed according to the search result to update the floorplan.

### CROSS-REFERENCE TO RELATED APPLICATION

This application claims priority to Chinese Patent Application No. 202210266012.3, filed on Mar. 17, 2022, the entire content of which is incorporated herein by reference.

### TECHNICAL FIELD

The present disclosure relates to the field of residential intelligent design and in particular, to a method and device for floorplan generation.

### BACKGROUND

Architecture design is a relatively professional and complex work, which usually requires a designer to receive years of professional design training and a certain amount of experience accumulation. The designer needs to combine his/her own professional knowledge and design experience to design a residential unit floorplan. During the design process, the designer needs to sketch manually the layout and shapes of rooms, for example, dining room, living room, bedrooms, bathrooms, in the residential floorplan layout to match the space requirements with the lifestyle. This work depends on the experience of designers. Therefore, a method is needed to generate floorplans automatically providing reference for designers or non-professional.

In recent years, numerous studies have used deep learning to generate residential floorplans.

However, the deep learning training often requires a large amount of data. In a case of limited data, the generalization ability of the model is often affected. Because the model learns the characteristics of the data, the quality of the data determines the effect of the model training to some extent. As for residential units, because there are good and bad floorplans in the real estate market, training based entirely on the floorplans of these units may affect the quality of the generated results. Because different regions often have different requirements for residential design, and relevant design specifications continue to change with time, it is often difficult for models trained based on specific data to adapt to these differences and changes.

In the field of architectural design, researchers usually use meta-heuristic algorithms to optimize the performance of buildings, such as energy consumption, ventilation, and lighting. The meta-heuristic algorithm can search for an ideal variable combination in a nonlinear complex space that meets constraints of an objective function through a random or approximately random method, which is a product of a combination of a random algorithm and a local search algorithm for solving optimization problems. Algorithms, for example, simulated annealing algorithm, genetic algorithm, ant colony optimization algorithm, particle swarm optimization algorithm, artificial fish swarm algorithm, etc., have a certain degree of blindness in the search process. Because it is not easy to precisely constrain the directionality of the search, a large number of useless solutions are generated in the iterations, which affect the efficiency and effect of the algorithm. When optimizing building performance, the spatial layout of the building is often roughly determined, and only limited adjustments to the building shape are required, so the search space is relatively small. Because a goal of building performance optimization is mostly that an optimization result is better than a current result, there are many feasible solutions, and the meta-heuristic algorithm has better applicability on such problems. However, for the floorplan of the residential units, due to limitation of external environmental conditions and complex correlation between internal rooms, under a combination of many variables, the number of feasible solutions is very small, and the search space is often huge. In terms of efficiency or results, the applicability is not ideal. In actual engineering practice, due to the huge search space of many problems, there are many local extremums, which makes the algorithm easy to fall into local optimum and cannot obtain effective results.

Therefore, there is a need for a method to automatically generate the floorplan with aid of a computer for designers, and to explore reasonable floorplans.

### SUMMARY

In accordance with the disclosure, there is provided a method for floorplan generation, including obtaining a current status of a floorplan and room information of one or more rooms to be deployed, according to the current status of the floorplan and the room information of the one or more rooms to be deployed, performing multiple Monte Carlo tree searches to obtain a search result, and deploying a room of the one or more rooms to be deployed according to the search result to update the floorplan.

Also in accordance with the disclosure, there is provided a device for floorplan generation, including a memory storing a computer program, and a processor configured to execute the computer program to obtain a current status of a floorplan and room information of one or more rooms to be deployed, according to the current status of the floorplan and the room information of the one or more rooms to be deployed, perform multiple Monte Carlo tree searches to obtain a search result, and deploy a room of the one or more rooms to be deployed according to the search result to update the floorplan.

Also in accordance with the disclosure, there is provided a non-transitory computer-readable storage medium storing a computer program that, when the computer program being executed by a processor, causing the processor to perform obtaining a current status of a floorplan and room information of one or more rooms to be deployed, according to the current status of the floorplan and the room information of the one or more rooms to be deployed, performing multiple Monte Carlo tree searches to obtain a search result, and deploying a room of the one or more rooms to be deployed according to the search result to update the floorplan.

### BRIEF DESCRIPTION OF THE DRAWINGS

FIG. 1 is a schematic diagram of an application scenario of floorplan generation consistent with the embodiments of the disclosure.

FIG. 2 is a schematic diagram of a floorplan generation process based on Monte Carlo tree search consistent with the embodiments of the disclosure.

FIG. 3 is a schematic flow chart of a method for floorplan generation consistent with the embodiments of the disclosure.

FIG. 4 is a schematic flow chart of the method for the floorplan generation consistent with the embodiments of the disclosure.

FIGS. 5A-5D are schematic diagrams of a vectorization method of the floorplan consistent with the embodiments of the disclosure.

FIG. 6 is a schematic diagram of a device for floorplan generation consistent with the embodiments of the disclosure.

FIG. 7 is a schematic structural diagram of a computer device consistent with the embodiments of the disclosure.

### DETAILED DESCRIPTION OF THE EMBODIMENTS

Technical solutions of the present disclosure will be described with reference to the drawings. It will be appreciated that the described embodiments are some rather than all of the embodiments of the present disclosure. Other embodiments conceived by those having ordinary skills in the art on the basis of the described embodiments without inventive efforts should fall within the scope of the present disclosure.

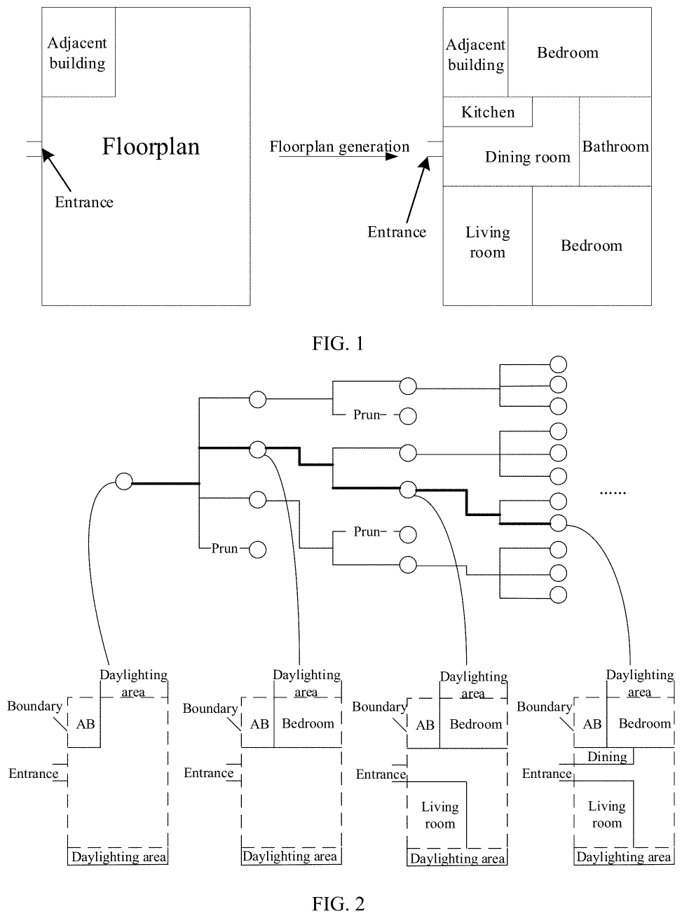

FIG. 1 is a schematic diagram of an application scenario of floorplan generation consistent with the embodiments of the disclosure. As shown in FIG. 1, through the technical solution of the present disclosure, the rooms can be rationally deployed on the floorplan of the existing residential unit. Besides residential unit, it can be understood that the residential units can be equivalently replaced by other buildings in various other possible business scenarios.

FIG. 2 is a schematic diagram of a floorplan generation process based on Monte Carlo tree search consistent with the embodiments of the disclosure. As shown in FIG. 2, the floorplan generation process includes a sequential generation process, that is, different rooms to be deployed are deployed into a boundary area one by one in a certain order. First, a status of a floorplan is initialized according to a design conditions, such as a boundary condition, a room type, etc. Secondly, based on the current status of the floorplan, a possibility of the deployment situation of remaining room is explored through Monte Carlo tree search algorithm. Feasible probabilities of different deployment situations of the room to be deployed are calculated according to a result of an evaluation function and an upper limit confidence interval algorithm formula. An optimal deployment situation of the room to be deployed is then selected. Vector parameters of the room to be deployed are output. Thirdly, the status of the floorplan is updated according to the vector parameters. The Monte Carlo tree search is performed again. By continuously repeating the above processes, a final floorplan is obtained until all the rooms to be deployed are deployed.

The Monte Carlo tree search is used to solve optimal decision problems. In the Monte Carlo tree search, various feasible solutions of the problem are searched for by constructing a search graph, updating a weight of each node in the search graph according to a satisfaction degree of a result to a goal, and finally selecting a next action according to the weight of the node to realize action decision-making. The Monte Carlo tree search combines a generality of stochastic simulation and an accuracy of tree search. Through the stochastic simulation, the feasible probabilities of different strategies can be obtained. By pruning tree nodes, a large number of unnecessary options can be eliminated, thereby compressing a search space to effectively solve the problem of relatively large search space. The Monte Carlo tree search is usually applied to combinatorial game problems, for example, chess, Go, etc. The Monte Carlo tree search also has a wide range of applications in other fields.

The floorplan problem targeted by the present disclosure is a combinatorial optimization problem, that is, to solve an optimal combination of various rooms within given boundary conditions. Through the Monte Carlo tree search, an optimal decision-making on locations and sizes of different rooms can be realized, so as to obtain an optimal floorplan. The floorplan may also refer as a house layout.

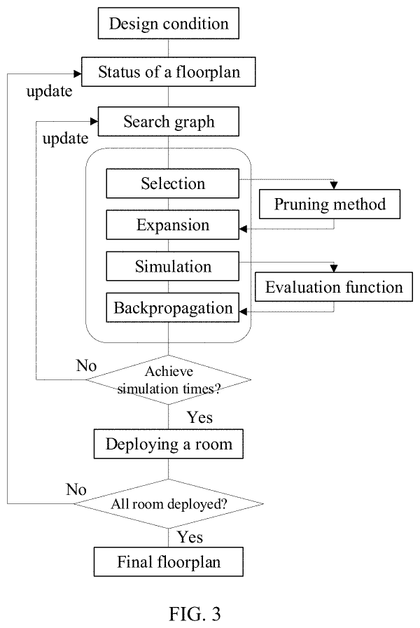

FIG. 3 is a schematic flow chart of a method for floorplan generation consistent with the embodiments of the disclosure. As shown in FIG. 3, the method for the floorplan generation includes determining one or more design conditions including an external environment and room information of one or more rooms to be deployed, initializing a status of a floorplan according to the one or more design conditions, constructing a search graph according to the status of the floorplan, and based on the constructed search graph, one or more possible floorplans are explored through Monte Carlo tree search algorithm. The Monte Carlo tree search algorithm is divided into four processes: selection, expansion, simulation, and backpropagation.

In the selection process, a node is selected as a root node according to the current search graph, and the root node is expanded based on the root node.

In the expansion process, possibilities (e.g., first sub-nodes) of one or more deployment situations of a room to be deployed in a next process is determined according to the current status of the floorplan. The possibilities are screened through a pruning function to obtain one or more actual expandable nodes (e.g., second sub-nodes) after pruning. One of the one or more actual expandable nodes is selected to continue to be expanded.

In the simulation process, a random search is performed based on the one or more newly expanded nodes. Then a result of the random search is evaluated by an evaluation function.

In the backpropagation process, according to a score of the evaluation function, a weight of a relevant node in the search graph is updated through an upper limit confidence interval algorithm formula. The relevant node refers to the selected node in the expansion process, for example, one of the plurality of second sub-nodes. In some embodiments, only one node is selected in the expansion process for a one-time backpropagation process. The Monte Carlo tree search algorithm is repeated continuously until a set number of iterations is reached. In some embodiments, after the Monte Carlo tree search algorithm is repeated continuously until a set number of iterations is reached, a plurality of weights of a plurality of relevant nodes are updated.

Finally, according to the updated weights of the nodes in the search graph, an optimal node is selected to deploy the room to be deployed. In some embodiments, the optimal node is determined after a certain number of samplings are performed. If the number of samplings is not enough, the plurality of weights of the plurality of relevant nodes have no statistical significance. The status of the floorplan is updated. After all the rooms to be deployed are deployed, a final floorplan is output. In some embodiments, the final floorplan may be output (e.g., printed and/or drawn) on a substance or a medium, such as a paper, a film, a cloth, etc.

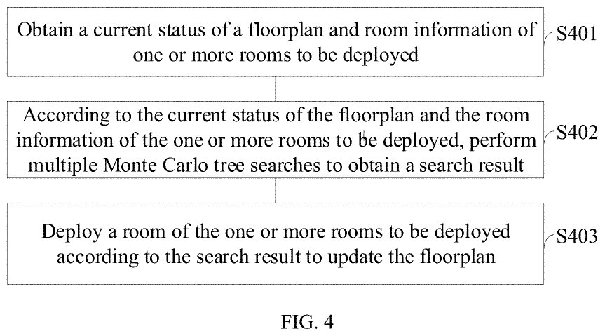

FIG. 4 is a schematic flow chart of the method for the floorplan generation consistent with the embodiments of the disclosure. As shown in FIG. 4, the method for the floorplan generation includes the following processes.

At S401, a current status of a floorplan and room information of one or more rooms to be deployed are obtained.

In some embodiments, obtaining the current status of the floorplan includes obtaining a design condition of the floorplan, where the design condition includes a boundary range of the floorplan, a location of a main entrance, a daylighting area, and/or information of one or more adjacent buildings, and determining the current status of the floorplan according to the design condition.

At S402, according to the current status of the floorplan and the room information of the one or more rooms to be deployed, multiple Monte Carlo tree searches are performed to obtain a search result.

In some embodiments, according to the current status of the floorplan and the room information of the one or more rooms to be deployed, performing the multiple Monte Carlo tree searches to obtain the search result may include constructing a current search graph according to the current status of the floorplan, where each of a plurality of nodes of the current search graph represents a deployment situation of the room of the one or more rooms to be deployed, determining the room information of the room of the one or more rooms to be deployed, and according to the room information of the room of the one or more rooms to be deployed, performing multiple operations on the current search graph through Monte Carlo tree search algorithm to obtain the search result, the search result including an optimal node of the current search graph.

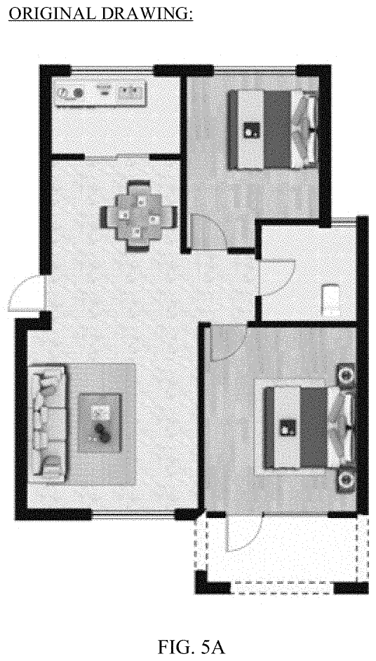

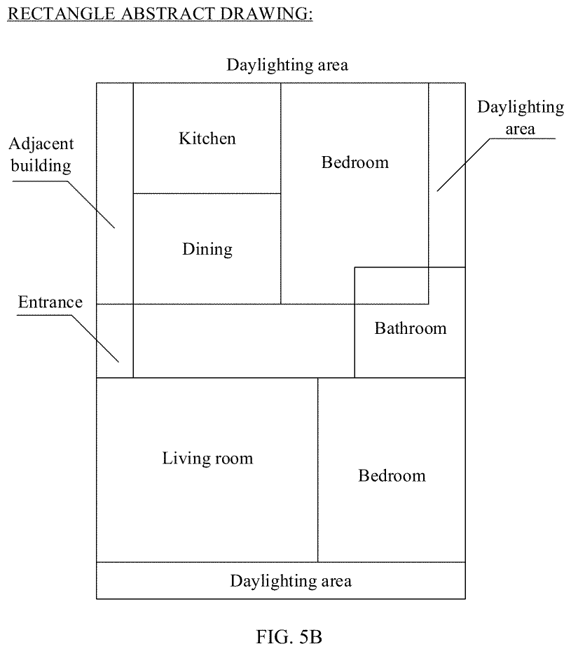

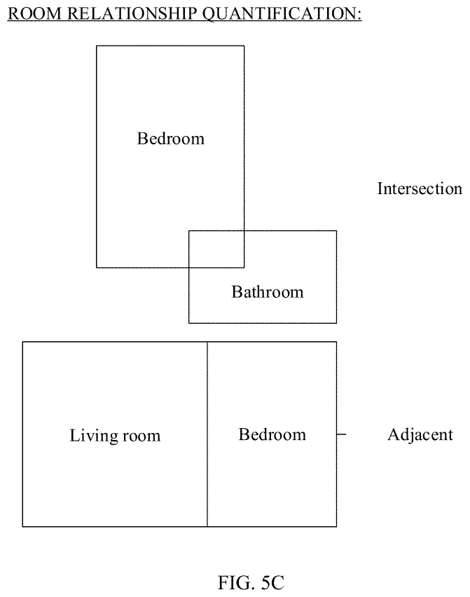

FIGS. 5A-5D are schematic diagrams of a vectorization method of the floorplan consistent with the embodiments of the disclosure. As shown in FIG. 5A, a room type includes two types: a closed room type, for example, a bedroom, a bathroom, etc., and an open room type, for example, a living room, a dining room, etc. A combination of a plurality of rooms can be abstracted as a combination of a plurality of rectangles. The room information can be described by a size and coordinates. As shown in FIG. 5C, most of the rooms are in an “adjacent” relationship, but some rooms are in an “intersection” relationship. In the intersection relationship, a part of a room “invades” another room. At this time, a plane form of the “invaded” room is a concave polygon, but it can still be regarded as a complete rectangle through a way of filling. Therefore, the combination of all rooms in a floorplan can be regarded as a combination of the plurality of rectangles. According to the abstracted rectangular room, a room form can be quantified. As shown in FIG. 5D, the room form quantification includes room position coordinates and the size of the room. The size of the room includes a width and a depth of the room. Therefore, the entire floorplan can be described using a set of x-axis coordinates, y-axis coordinates, the width dimensions, and the depth dimensions.

According to the obtained boundary range of the current floorplan, the location of the main entrance, the daylighting area, and the information of the one or more adjacent buildings, the current status of the floorplan is determined, and the current search graph is constructed according to the current status of the floorplan. In some embodiments, some of the one or more rooms to be deployed may have been deployed, and the current status of the floorplan may also include the determined deployment situations of the some of the one or more rooms to be deployed. It can be understood that each combination of coordinates and dimensions of a room to be deployed is a node in the search graph.

In some embodiments, each of the multiple operations on the current search graph through the Monte Carlo tree search algorithm may include the following processes.

At process A, a node is selected as a root node according to the current search graph, and the root node is expanded according to the root node to obtain a plurality of first sub-nodes. The sub-nodes may refer to child nodes of the root node.

In some embodiments, each of the one or more rooms to be deployed has a size range, such as a width range and a depth range. According to coordinates of each of the one or more rooms to be deployed, all combinations of sizes and coordinates are obtained. Each node of the search graph corresponds to a possible deployment situation of one of the one or more rooms to be deployed, that is, each node of the search graph corresponds to a set of a combination of the size and the coordinates.

In some embodiments, selecting a node as the root node includes selecting a node that needs to be expanded most urgently as the root node from a situation where a decision is to be made. For example, if the room currently to be deployed is a master bedroom, and the current floorplan has not deployed a room, the current status of the floorplan is the root node. The master bedroom is started to be deployed based on the current status of floorplan, and a plurality of floorplans with a plurality of deployment situations of the master bedroom can be obtained. Each of the plurality of floorplans after the master bedroom is deployed is a first sub-node.

At process B, the plurality of first sub-nodes are screened through a pruning method to obtain a plurality of second sub-nodes. The plurality of second sub-nodes represent actual expandable nodes after pruning.

In some embodiments, the pruning method may include a position pruning and a size pruning.

To exclude unnecessary options and compress an exploration space, the search graph of the floorplan is pruned. Pruning can compress the exploration space by excluding one or more obviously inappropriate room forms.

For example, if the current status of the floorplan, that the floorplan has not deployed a room, is selected as the root node, and the root node is expanded, a plurality of floorplans with a plurality of deployment situations of the master bedroom are a plurality of first sub-node. Some of the deployment situations of the master bedroom cannot meet use requirements, therefore the deployment situations that do not meet the use requirements are screened out to obtain a plurality of actual expandable floorplans after the pruning, which are a plurality of second sub-nodes. If one of the plurality of actual expandable floorplans after pruning is selected as the root node, and the root node is expanded, that is, a next room to be deployed, such as a guest bedroom, is deployed, a plurality of floorplans with deployment situations of the guest bedrooms are obtained after the master bedroom is deployed. The plurality of floorplans after the master bedroom is deployed is the first sub-nodes. A plurality of floorplans after the guest bedroom is deployed are pruned to obtain results as the second sub-nodes.

In some embodiments, all room forms are represented by rectangles. Although there are irregular forms in the floorplan of the building, most of the rooms are rectangular. Therefore, representing all the rooms in the floorplan with a rectangle can describe the floorplan for most buildings, simplify calculation difficulty, and achieve a balance between generalization ability and computational efficiency.

The position pruning includes defining a spatial relationship between rooms (such as intersection, adjacent), and pruning according to the spatial relationship. The size pruning includes determining whether an area interval is satisfied, and pruning in response to the area interval being not unsatisfied. The position pruning can eliminate unnecessary coordinates for placing a room. The size pruning can control a size of the room after the position of the room is determined. All feasible deployment situations of a next room in a specific floorplan can be obtained by pruning.

In some embodiments, a formula of the position pruning includes:

Set_{coords}ⁱ=Vᵣ(xᵣⁱ, yᵣⁱ)∩V_{b}(x_{b}ⁱ, y_{b}ⁱ)

where Set_{coords}ⁱ represents a set of placeable coordinates for an i-th room, Vᵣ(xᵣⁱ, yᵣⁱ) represents a placeable point for a room adjacent to the i-th room, V_{b}(x_{b}ⁱ, y_{b}ⁱ) represents placeable point of a remaining area after the i-th room is placed, (xᵣⁱ, yᵣⁱ) represents x-axis and y-axis coordinates of the placeable point for the room adjacent to the i-th room, and (x_{b}ⁱ, y_{b}ⁱ) represents x-axis and y-axis coordinates of the placeable point of the remaining area after the i-th room is placed. The remaining area may refer to a blank area in the floorplan.

Because the spatial relationship between rooms is defined in advance, all deployment situations of the one or more rooms to be deployed with appropriate location information can be obtained through intersection of the remaining area after the room to be deployed is placed and the placeable points of the rooms adjacent to the room to be deployed.

For example, as shown in FIG. 5C, it is defined in advance that a second bedroom intersects with a bathroom. According to the defined spatial relationship and the intersection of the points of the remaining area of the current floorplan, a plurality of possible deployment situations of the second bedroom can be determined.

In some embodiments, a formula of the size pruning includes:

Setᵣₒₒₘₛⁱ=Set_{coords}ⁱ×Set_{w}ⁱ×Set_{d}ⁱ

where Setᵣₒₒₘₛⁱ represents a set of placeable rooms for an i-th room, Set_{coords}ⁱ represents a set of placeable coordinates for the i-th room, and Set_{w}ⁱ represents a set of width of the i-th room, and Set_{d}ⁱ represents a set of depth of the i-th room.

By multiplying the set of coordinates and the set of size of the room to be deployed, the set of placeable rooms with a suitable size for the room to be deployed can be obtained.

At process C, a random search is performed based on the plurality of second sub-nodes, and a result of the random search is evaluated through an evaluation function.

In some embodiments, the evaluation function includes at least one of a room number evaluation, an intersection area evaluation, or an aisle evaluation. The aisle evaluation includes at least one of an aisle area evaluation, an aisle and room adjacency evaluation, or an aisle width evaluation.

Pruning is a strong constraint on the feasible solution of the floorplan, while the evaluation function is a weak constraint on the feasible solution of the floorplan. By scoring each result and updating a weight of each node of the search graph according to the score, the evaluation function can guide the algorithm to explore an optimal strategy.

In some embodiments, a formula of the evaluation function includes:

max Score=Sₙ+Sₒ+Sₚ

where, Score represents a total score of the floorplan, Sₙ represents a score of the number of rooms, Sₒ represents a score of the intersection area, and Sₚ represents a score of the aisle.

In some embodiments, a formula of the score of the number of rooms includes:

$${S}_{n} = \frac{{n}_{d}}{{n}_{t}}$$

where, n_{d} represents a number of rooms that have been deployed, and nₜ represents a total number of rooms planned to be deployed.

In some embodiments, a formula of the score of the intersection area includes:

$${S}_{o} = \frac{{\sum }_{i = 1}^{n} {s}_{r}^{i} - S ( {⋃}_{i = 1}^{n} {r}_{i} )}{{s}_{b}}$$

where, Σᵢ₌₁ⁿsᵣⁱ represents a total area of all deployed rooms, S(Uᵢ₌₁ⁿrᵢ) represents a total area of intersection of all deployed rooms, and s_{b} represents an area of the boundary range.

In some embodiments, a formula of the score of the aisle includes:

Sₚ=Pₒ+P_{w}+Pₐ

where, P_{w} represents a score of the aisle width, Pₐ represents a score of the aisle area, and Pₒ represents a score of the aisle and room adjacency.

In some embodiments, the score of the aisle width is expressed as:

$${P}_{w} = \{ \begin{matrix}1 , & w > {w}_{std} \\ \frac{{w}_{std} - w}{{w}_{std}} , & w < {w}_{std}\end{matrix}$$

where, w_{std} represents a minimum target width of the aisle, and w represents a current minimum width of the aisle.

In some embodiments, the score of the aisle area is expressed as:

$${P}_{d} = {\sum }_{i = 1}^{n} {d}_{i}$$

where dᵢ represents a distance from the aisle to the i-th room.

At process D, weights of relevant nodes in the search graph are updated according to the score of the evaluation function. The optimal node includes the node with a largest weight. In some embodiments, the relevant nodes include the plurality of second sub-nodes. The optimal node includes one of the plurality of second sub-nodes with the largest weight.

In some embodiments, a formula for updating the weights of the relevant nodes in the search graph includes:

$$W = \frac{{\sum }_{i = 1}^{n} {q}_{j}^{i}}{{n}_{j}} + c \sqrt{\frac{2 \times ln n}{{n}_{j}}}$$

where, W represents the weight of one of the plurality of second sub-nodes of the current search graph, nⱼ represents a number of visit times of the one of the plurality of second sub-nodes, qⱼ represents the one of the plurality of second sub-nodes, qⱼⁱ represents a value of the one of the plurality of second sub-nodes qⱼ in an i-th simulation, i represents a sequence number of the simulation, n represents a total number of visit times of the root node, and c represents a hyperparameter.

The hyperparameter c is a constant. A theoretical value of the hyperparameter c is \sqrt{2}. The larger the value of c, the more inclined to the breadth search. The smaller the value of c, the more inclined to the deep search.

At S403, a room of the one or more rooms to be deployed is deployed according to the search result to update the floorplan.

In some embodiments, the optimal node in the search result is obtained. The room to be deployed is deployed according to the deployment situation corresponding to the optimal node.

The method for the floorplan generation based on the Monte Carlo tree search consistent with the embodiments of the present disclosure can automatically search for the floorplan with a suitable combination of rooms according to the design condition (for example, the location of the main entrance, the daylighting area, the boundary range of the floorplan, and/or the information of the one or more adjacent buildings), to realize an automatic design of the floorplan. The method for the floorplan generation can effectively compress the search space through “pruning,” improve the search efficiency, and obtain the optimal floorplan result. At the same time, the method for the floorplan generation can guide the result based on the evaluation function and adapt to different design conditions by adjusting the evaluation function, thereby improving flexibility and expandability.

Based on the method for the floorplan generation based on the Monte Carlo tree search consistent with the embodiments of the present disclosure, a device for floorplan generation based on the Monte Carlo tree search is also provided.

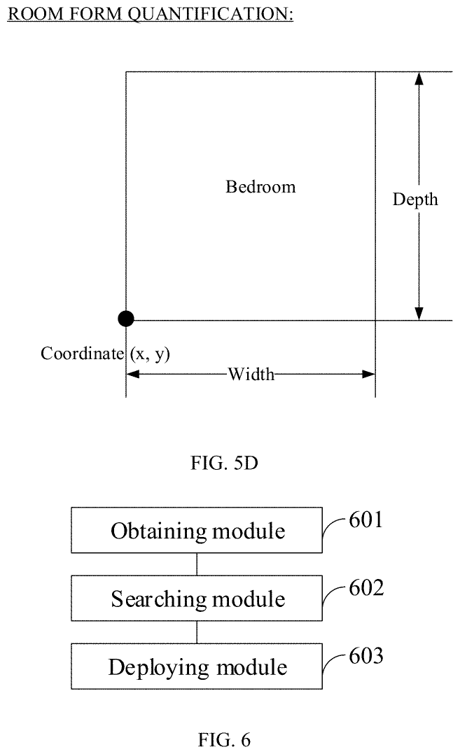

FIG. 6 is a schematic diagram of a device for floorplan generation consistent with the embodiments of the disclosure. The device may be divided into one or more program modules. The one or more program modules are stored in a storage medium, and are processed by one or more processors to execute the method for floorplan generation consistent with the embodiments of the present disclosure. As shown in FIG. 6, the device includes an obtaining module 601 configured to obtain a current status of a floorplan and room information of one or more rooms to be deployed, a searching module 602 configured to, according to the current status of the floorplan and the room information of the one or more rooms to be deployed, perform multiple Monte Carlo tree searches to obtain a search result, and a deploying module 603 configured to deploy a room of the one or more rooms to be deployed according to the search result to update the floorplan.

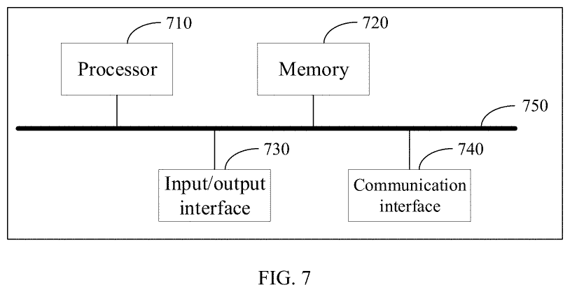

FIG. 7 is a schematic structural diagram of a computer device consistent with the embodiments of the disclosure. As shown in FIG. 7, the computer device includes a processor 710, a memory 720, an input/output interface 730, a communication interface 740, and a bus 750. The processor 710, the memory 720, the input/output interface 730, and the communication interface 740 are connected to each other within the device through the bus 750. The computer device can be used to execute the method for the floorplan generation consistent with the embodiments of the present disclosure.

The processor 710 may be implemented by a general-purpose central processing unit (CPU), a microprocessor, an application-specific integrated circuit (ASIC), or one or more integrated circuits. The processor 710 is configured to execute related programs to perform the method for the floorplan generation consistent with the embodiments of the present disclosure.

The memory 720 may be implemented in a form of a read-only memory (ROM), a random-access memory (RAM), a static storage device, a dynamic storage device, etc. The memory 720 can store operating systems and other application programs. When implementing the technical solutions provided by the embodiments of the present disclosure through software or firmware, the relevant program codes are stored in the memory 720 and executed by the processor 710.

The input/output interface 730 is configured to connect the input/output module to realize information input and output. The input/output module can be configured in the device as a component (not shown), and can also be connected externally to the device to provide corresponding functions. The input device may include a keyboard, a mouse, a touch screen, a microphone, various sensors, etc. The output device may include a display, a speaker, a vibrator, an indicator light, etc.

The communication interface 740 is configured to connect a communication module (not shown), to realize the communication interaction between the device and other devices. The communication module can realize communication through wired means (such as USB, network cable, etc.), and can also realize communication through wireless means (such as mobile network, WIFI, Bluetooth, etc.).

The bus 750 includes a path for transferring information between the various components of the device (e.g., the processor 710, the memory 720, the input/output interface 730, and the communication interface 740).

It should be noted that although the above device only shows the processor 710, the memory 720, the input/output interface 730, the communication interface 740, and the bus 750, the device may also include other components. In addition, those skilled in the art can understand that the above-mentioned device may only include components necessary to implement the technical solutions consistent with the embodiments of the present disclosure, and does not necessarily include all the components shown in the drawings.

The relational terms, such as “first” and “second” are only used to distinguish one entity or operation from another entity or operation, which may not indicate or imply any such actual relationship or order between the entities or operations. The terms “include,” “contain,” and any other variants are intended to cover non-exclusive inclusion, which cause a process, method, article, or device including a series of elements not only includes the listed elements, but also includes other elements that are not explicitly listed, or elements inherent to the process, method, article, or device. Unless otherwise defined, the use of “including a . . . ” followed by an element does not exclude the existence of another same element in the process, method, article, or device.

Those of ordinary skill in the art will appreciate that the example elements and algorithm steps described above can be implemented in electronic hardware, or in a combination of computer software and electronic hardware. Whether these functions are implemented in hardware or software depends on the specific application and design constraints of the technical solution. One of ordinary skill in the art can use different methods to implement the described functions for different application scenarios, but such implementations should not be considered as beyond the scope of the present disclosure.

Other embodiments of the disclosure will be apparent to those skilled in the art from consideration of the specification and practice of the embodiments disclosed herein. It is intended that the specification and examples be considered as example only and not to limit the scope of the disclosure, with a true scope and spirit of the invention being indicated by the following claims.

What is claimed is:

1. A method for floorplan generation, comprising:
obtaining a current status of a floorplan and room information of one or more rooms to be deployed;
according to the current status of the floorplan and the room information of the one or more rooms to be deployed, performing multiple Monte Carlo tree searches to obtain a search result; and
deploying a room of the one or more rooms to be deployed according to the search result to update the floorplan.

2. The method of claim 1, wherein obtaining the current status of the floorplan includes:
obtaining a design condition of the floorplan, the design condition including a boundary range of the floorplan, a location of a main entrance, a daylighting area, information of one or more adjacent buildings, or a combination thereof; and
determining the current status of the floorplan according to the design condition.

3. The method of claim 1, wherein according to the current status of the floorplan and the room information of the one or more rooms to be deployed, performing, by the processor, the multiple Monte Carlo tree searches to obtain the search result, includes:
constructing a current search graph according to the current status of the floorplan, each of a plurality of nodes of the current search graph representing a deployment situation of the room of the one or more rooms to be deployed;
determining the room information of the room of the one or more rooms to be deployed; and
according to the room information of the room of the one or more rooms to be deployed, performing multiple operations on the current search graph through Monte Carlo tree search algorithm to obtain the search result, the search result including an optimal node of the current search graph.

4. The method of claim 3, wherein each of the multiple operations on the current search graph through the Monte Carlo tree search algorithm includes:
selecting a node as a root node according to the current search graph, and expanding the root node according to the root node to obtain a plurality of first sub-nodes;
screening the plurality of first sub-nodes through a pruning method to obtain a plurality of second sub-nodes, the plurality of second sub-nodes representing actual expandable nodes after pruning;
performing a random search based on the plurality of second sub-nodes, and evaluating a result of the random search through an evaluation function; and
updating a weight of one of the plurality of second sub-nodes of the current search graph according to a score of the evaluation function, the optimal node including one of the plurality of second sub-nodes with a largest weight.

5. The method of claim 4, wherein updating the weights of the plurality of second sub-nodes of the current search graph includes:
updating the weights of the plurality of second sub-nodes of the current search graph using:
$$W = \frac{{\sum }_{i = 1}^{n} {q}_{j}^{i}}{{n}_{j}} + c \sqrt{\frac{2 \times ln n}{{n}_{j}}}$$
wherein W represents the weight of one of the plurality of second sub-nodes of the current search graph, nⱼ represents a number of visit times of the one of the plurality of second sub-nodes, qⱼ represents the one of the plurality of second sub-nodes, qⱼⁱ represents a value of the one of the plurality of second sub-nodes qⱼ in an i-th simulation, i represents a sequence number of the simulation, n represents a total number of visit times of the root node, and c represents a hyperparameter.

6. The method of claim 4, wherein the pruning method includes a position pruning and a size pruning.

7. The method of claim 6, wherein a formula of the position pruning includes:
Set_{coords}ⁱ=Vᵣ(xᵣⁱ, yᵣⁱ)∩V_{b}(x_{b}ⁱ, y_{b}ⁱ)
wherein Set_{coords}ⁱ represents a set of placeable coordinates for an i-th room, Vᵣ(xᵣⁱ, yᵣⁱ) represents a placeable point for a room adjacent to the i-th room, V_{b}(x_{b}ⁱ, y_{b}ⁱ) represents placeable point of a remaining area after the i-th room is placed, (xᵣⁱ, yᵣⁱ) represents x-axis and y-axis coordinates of the placeable point for the room adjacent to the i-th room, and (x_{b}ⁱ, y_{b}ⁱ) represents x-axis and y-axis coordinates of the placeable point of the remaining area after the i-th room is placed.

8. The method of claim 6, wherein a formula for the size pruning includes:
Setᵣₒₒₘₛⁱ=Set_{coords}ⁱ×Set_{w}ⁱ×Set_{d}ⁱ
wherein Setᵣₒₒₘₛⁱ represents a set of placeable rooms for an i-th room, Set_{coords}ⁱ represents a set of placeable coordinates for the i-th room, and Set_{w}ⁱ represents a set of width of the i-th room, and Set_{d}ⁱ represents a set of depth of the i-th room.

9. The method of claim 4, wherein the evaluation function includes at least one of a room number evaluation, an intersection area evaluation, or an aisle evaluation.

10. The method of claim 4, wherein the evaluation function includes an aisle evaluation, the aisle evaluation including at least one of an aisle area evaluation, an aisle and room adjacency evaluation, or an aisle width evaluation.

11. A device for floorplan generation, comprising:
a memory storing a computer program; and
a processor configured to execute the computer program to:
obtain a current status of a floorplan and room information of one or more rooms to be deployed;
according to the current status of the floorplan and the room information of the one or more rooms to be deployed, perform multiple Monte Carlo tree searches to obtain a search result; and
deploy a room of the one or more rooms to be deployed according to the search result to update the floorplan.

12. The device of claim 11, wherein the processor is further configured to execute the computer program to:
obtain a design condition of the floorplan, the design condition including a boundary range of the floorplan, a location of a main entrance, a daylighting area, and information of one or more adjacent buildings; and
determine the current status of the floorplan according to the design condition.

13. The device of claim 11, wherein the processor is further configured to execute the computer program to:
construct a current search graph according to the current status of the floorplan, each of a plurality of nodes of the current search graph representing a deployment situation of the room of the one or more rooms to be deployed;
determine the room information of the room of the one or more rooms to be deployed; and
according to the room information of the room of the one or more rooms to be deployed, perform multiple operations on the current search graph through Monte Carlo tree search algorithm to obtain the search result, the search result including an optimal node of the current search graph.

14. The device of claim 13, wherein the processor is further configured to execute the computer program to:
select a node as a root node according to the current search graph, and expand the root node according to the root node to obtain a plurality of first sub-nodes;
screen the plurality of first sub-nodes through a pruning method to obtain a plurality of second sub-nodes, the plurality of second sub-nodes representing actual expandable nodes after pruning;
perform a random search based on the plurality of second sub-nodes, and evaluate a result of the random search through an evaluation function; and
update a weight of one of the plurality of second sub-nodes of the current search graph according to a score of the evaluation function, the optimal node including one of the plurality of second sub-nodes with a largest weight.

15. The device of claim 14, wherein the processor is further configured to execute the computer program to:
update the weights of the plurality of second sub-nodes of the current search graph using:
$$W = \frac{{\sum }_{i = 1}^{n} {q}_{j}^{i}}{{n}_{j}} + c \sqrt{\frac{2 \times ln n}{{n}_{j}}}$$
wherein W represents the weight of one of the plurality of second sub-nodes of the current search graph, nⱼ represents a number of visit times of the one of the plurality of second sub-nodes, qⱼ represents the one of the plurality of second sub-nodes, qⱼⁱ represents a value of the one of the plurality of second sub-nodes qⱼ in an i-th simulation, i represents a sequence number of the simulation, n represents a total number of visit times of the root node, and c represents a hyperparameter.

16. The device of claim 14, wherein the pruning method includes a position pruning and a size pruning.

17. The device of claim 16, wherein a formula of the position pruning includes:
Set_{coords}ⁱ=Vᵣ(xᵣⁱ, yᵣⁱ)∩V_{b}(x_{b}ⁱ, y_{b}ⁱ)
wherein Set_{coords}ⁱ represents a set of placeable coordinates for an i-th room, Vᵣ(xᵣⁱ, yᵣⁱ) represents a placeable point for a room adjacent to the i-th room, V_{b}(x_{b}ⁱ, y_{b}ⁱ) represents placeable point of a remaining area after the i-th room is placed, (xᵣⁱ, yᵣⁱ) represents x-axis and y-axis coordinates of the placeable point for the room adjacent to the i-th room, and (x_{b}ⁱ, y_{b}ⁱ) represents x-axis and y-axis coordinates of the placeable point of the remaining area after the i-th room is placed.

18. The device of claim 16, wherein a formula for the size pruning includes:
Setᵣₒₒₘₛⁱ=Set_{coords}ⁱ×Set_{w}ⁱ×Set_{d}ⁱ
wherein Setᵣₒₒₘₛⁱ represents a set of placeable rooms for an i-th room, Set_{coords}ⁱ represents a set of placeable coordinates for the i-th room, and Set_{w}ⁱ represents a set of width of the i-th room, and Set_{d}ⁱ represents a set of depth of the i-th room.

19. The device of claim 14, wherein the evaluation function includes at least one of a room number evaluation, an intersection area evaluation, or an aisle evaluation.

20. A non-transitory computer-readable storage medium storing a computer program that, when the computer program being executed by a processor, causing the processor to perform:
obtaining a current status of a floorplan and room information of one or more rooms to be deployed;
according to the current status of the floorplan and the room information of the one or more rooms to be deployed, performing multiple Monte Carlo tree searches to obtain a search result; and
deploying a room of the one or more rooms to be deployed according to the search result to update the floorplan.
